(19) United States
(12) Patent Application Publication
(10) Pub. No.: US 2011/0240097 A1
(43) Pub. Date: Oct. 6, 2011

(54) CONCENTRATING SOLAR ENERGY COLLECTOR SYSTEM WITH PHOTOVOLTAIC CELLS

(76) Inventor: Dale E. Polk, JR., Titusville, FL (US)

(21) Appl. No.: 13/080,733

(22) Filed: Apr. 6, 2011

Related U.S. Application Data
(60) Provisional application No. 61/321,334, filed on Apr. 6, 2010.

(51) Int. Cl. H01L 31/052

(52) U.S. Cl. 136/246

(57) ABSTRACT

A solar energy collector system includes a solar collector configured to reflect sunlight to a diffused focal point, and a photovoltaic cell assembly carried by the solar collector. The photovoltaic cell assembly includes a collector housing positioned at the diffused focal point to receive the reflected sunlight, and photovoltaic cells within the collector housing to generate electricity based on the reflected sunlight. The collector housing includes a cooling liquid to cool the photovoltaic cells when generating the electricity.

### RELATED APPLICATION

This application claims the benefit of U.S. Provisional Application Ser. No. 61/321,334 filed Apr. 6, 2010, the entire contents of which are incorporated herein by reference.

### FIELD OF THE INVENTION

The present invention relates to the field of solar energy collector systems, and more particularly, to a concentrating solar energy collector system operating with photovoltaic cells.

### BACKGROUND OF THE INVENTION

There are a variety of solar energy collector systems available for converting solar energy into other forms of energy that can be more readily used or stored. Solar energy collector systems may be designed for unconcentrated sunlight or for concentrated sunlight.

Solar energy collector systems made up of photovoltaic cells normally uses unconcentrated or ambient sunlight, wherein the photovoltaic cells convert sunlight into electricity. Since the sunlight is spread out over the surface of the photovoltaic cells, large panels of photovoltaic cells are necessary, A disadvantage of this approach is that large amounts of silicon and photovoltaic materials are required. Also, the panels are usually mounted in a fixed position and have limited applicability.

Solar energy collector systems made up of lenses or mirrors use concentrated sunlight to focus a large area of sunlight onto a small area. Concentrating collectors of this type normally require a tracking system to keep the focal point upon its target as the sun moves across the sky. Concentrating collectors are designed to operate at high temperatures, thus substantially increasing the versatility of solar energy collector systems incorporating these collectors over systems employing panel collectors.

For example, a parabolic trough collector includes a linear parabolic reflector that concentrates light onto a conduit positioned along the reflector's focal line. The conduit is filled with a liquid that is heated as it flows therethrough. Similarly, concentrating linear Fresnel reflectors use many thin mirror strips instead of parabolic mirrors to concentrate sunlight onto conduits filled with a liquid. This has the advantage that flat mirrors can be used which are much cheaper than parabolic mirrors, and that more reflectors can be placed in the same amount of space, allowing more of the available sunlight to be used.

Concentrating collectors may also be used with photovoltaic cells for the purpose of producing electrical power. For example, Solar System Pty Ltd of Australia provides a dish concentrator using photovoltaic cells. The dish concentrator includes curved reflecting mirrors mounted on a frame that tracks the sun throughout the day that then delivers concentrated sunlight to photovoltaic cells. The photovoltaic cells are arranged as an array of photovoltaic cells suspended at the focal point of the mirrors. Since photovoltaic cell performance decreases as cell temperature increases, and the sunlight is concentrated several hundred times its normal, effective cooling is necessary to achieve efficient performance and to achieve an efficient operating life. Solar System Pty Ltd uses a closed loop liquid-to-ambient heat exchanger cooling system.

Another example of a concentrating collector that uses photovoltaic cells is disclosed by Sunenergy Pty Ltd of Australia, where the photovoltaic concentrator is configured as an array that is placed on water rather then on land. Each element of the floating array comprises a raft supporting a solar tracking lens and a partially submerged water cooled photovoltaic cell assembly. By arranging the photovoltaic cell concentrators in an array that is placed on water rather then on land, efficient cooling of the photovoltaic cells is provided.

Even in view of the advances made in concentrating collectors operating with photovoltaic cells for the purpose of producing electrical power, photovoltaic cells may experience both short-term (efficiency loss) and long-term (irreversible damage) degradation due to excess temperatures.

### SUMMARY OF THE INVENTION

In view of the foregoing background, it is therefore an object of the present invention to improve the operating life and performance of photovoltaic cells operating with concentrated collectors.

This and other objects, advantages and features in accordance with the present invention are provided by a solar energy collector system comprising at least one solar collector configured to reflect sunlight to a diffused focal point, and at least one photovoltaic cell assembly carried by the at least one solar collector. The at least one photovoltaic cell assembly may comprise a collector housing positioned at the diffused focal point to receive the reflected sunlight, and a plurality of photovoltaic cells within the collector housing to generate electricity based on the reflected sunlight. The diffused sunlight advantageously helps to lower the exposed temperature of the photovoltaic cell assembly, which in turn increases its efficiency and operating life.

Each photovoltaic cell assembly may further comprise a cooling liquid within the collector housing to cool the photovoltaic cells when generating the electricity. The cooling liquid advantageously further lowers the exposed temperature of the photovoltaic cell assembly.

Each photovoltaic cell assembly may further comprise a protective liner covering the photovoltaic cells to prevent contact with the cooling liquid. Alternatively, each photovoltaic cell assembly may further comprise a protective liner enclosing the cooling liquid to prevent contact with the photovoltaic cells.

Each solar collector may comprise a plurality of stepped sidewall sections adjacent one another to generate the diffused focal point. In other words, each solar collector may be configured as a Fresnel lens.

Each solar collector may be formed as a monolithic unit comprising a thermoplastic material and/or a thermosetting material. Each solar collector may comprise a reflective surface comprising a reflective film and/or a reflective coating. Consequently, the use of mirrors is avoided, which would significantly add to the weight of each solar collector. Each solar collector may be configured as a dish or a parabolic trough, for example.

The solar energy collector system may further comprise a common support for carrying a plurality of solar collectors, and a rotator assembly configured to rotate the common support and the plurality of solar collectors based on position of the sun. The solar energy collector system may further comprise at least one tilt assembly configured to adjust a latitudinal angle of the common support and the plurality of solar collectors with respect to ground.

Another aspect is directed to a method for generating electricity using a solar energy collector system as described above. The method may comprise positioning the at least one solar collector to reflect the sunlight to generate a diffused focal point, and positioning the at least one photovoltaic cell assembly at the diffused focal point. The electricity is generated at based on the at least one photovoltaic cell receiving the reflected sunlight. The method may further comprise cooling the at least photovoltaic cell with a cooling liquid when generating the electricity.

### BRIEF DESCRIPTION OF THE DRAWINGS

FIG. 1 is a perspective view of a concentrating solar energy collector system in accordance with the present invention.

FIG. 2 is a cross-sectional side view of a solar dish collector and its photovoltaic cell assembly in accordance with the present invention.

FIG. 3 is a more detailed cross-sectional side view of the sidewall sections of the solar dish collector cell reflecting sunlight to its photovoltaic cell assembly as shown in FIG. 2.

FIG. 4 is a more detailed side view of the rotator and tilt assemblies for rotating the solar dish collectors in accordance with the present invention.

FIG. 5 is a flowchart illustrating a method for generating electricity using a solar energy collector system in accordance with the present invention.

FIG. 6 is a side view of another embodiment of the concentrating solar energy collector system in accordance with the present invention.

FIG. 7 is a perspective side view of the parabolic trough shown in FIG. 6.

FIG. 8 is a perspective top view of the parabolic trough shown in FIG. 6.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

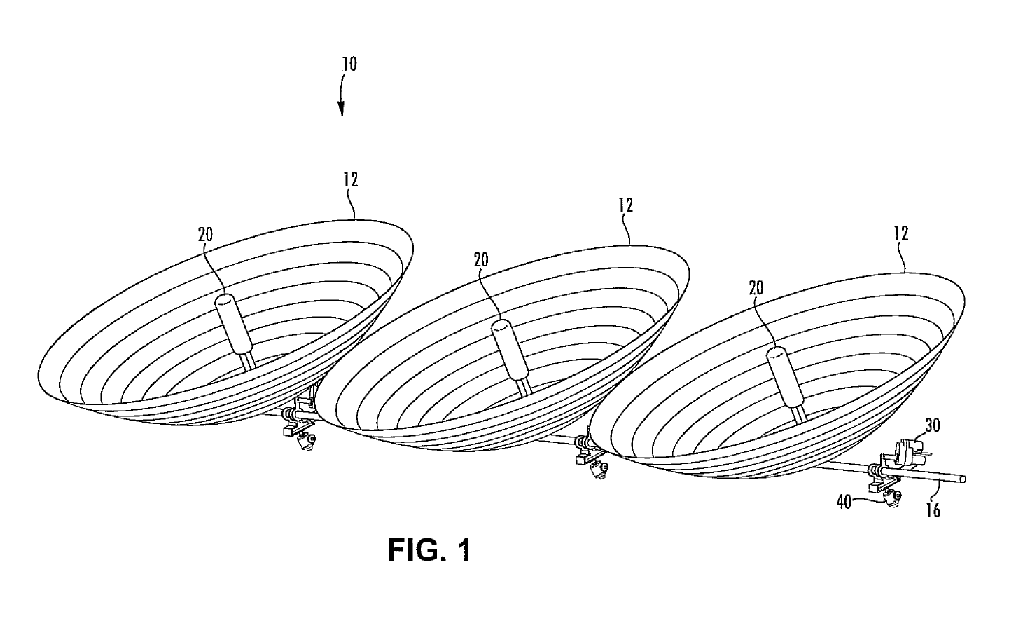

Referring initially to FIG. 1, the illustrated concentrating solar energy collector system 10 comprises a plurality of spaced apart solar dish collectors 12 mounted on a common support 16 that is rotatable in an east/west direction via a rotating assembly 30 for tracking movement of the sun throughout the day. The common support 16 may be a pipe, for example. The pipe 16 may also be raised/lowered via a tilting assembly 40 in a north/south direction to compensate for the seasonal rotation of the sun. Alternatively, instead of a common support 16, each solar dish collector 12 may be mounted on its own support.

Each solar dish collector 12 reflects diffused sunlight to a photovoltaic cell assembly 20. Instead of concentrating the sunlight to a narrow focal point on the photovoltaic cell assembly 20, the sidewalls of the solar dish collector are constructed so that the sunlight is diffused over a wider focal point. The diffused sunlight advantageously helps to lower the exposed temperature of the photovoltaic cell assembly 20, which in turn increases its efficiency and operating life. To help further lower the exposed temperature of the photovoltaic cell assembly 20, the photovoltaic cells themselves may be placed within a container holding a cooling liquid, such as water, for example.

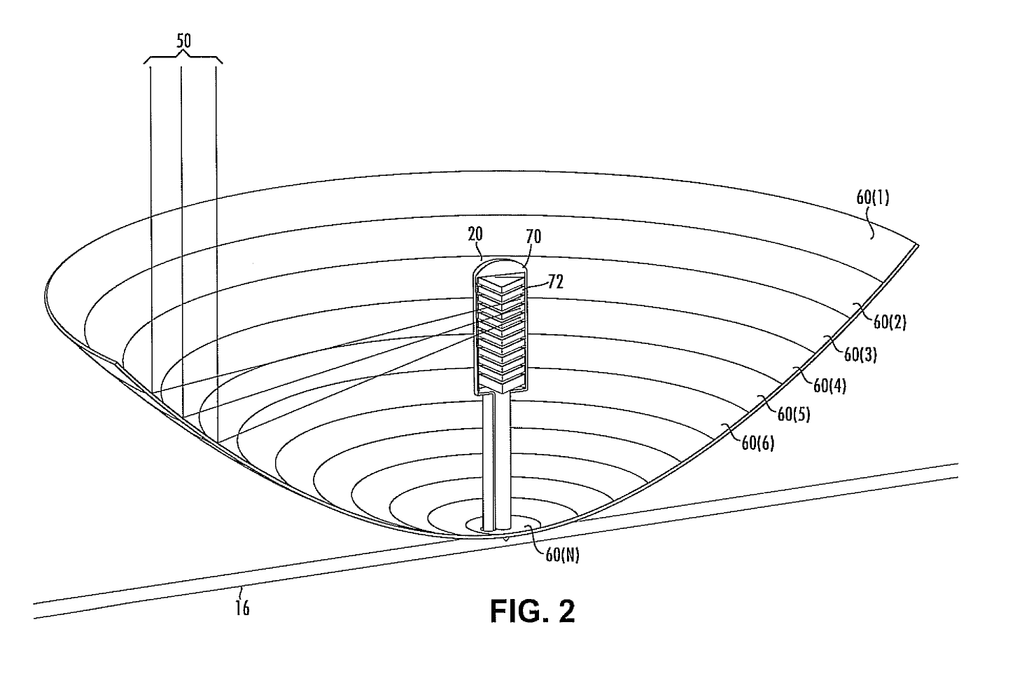

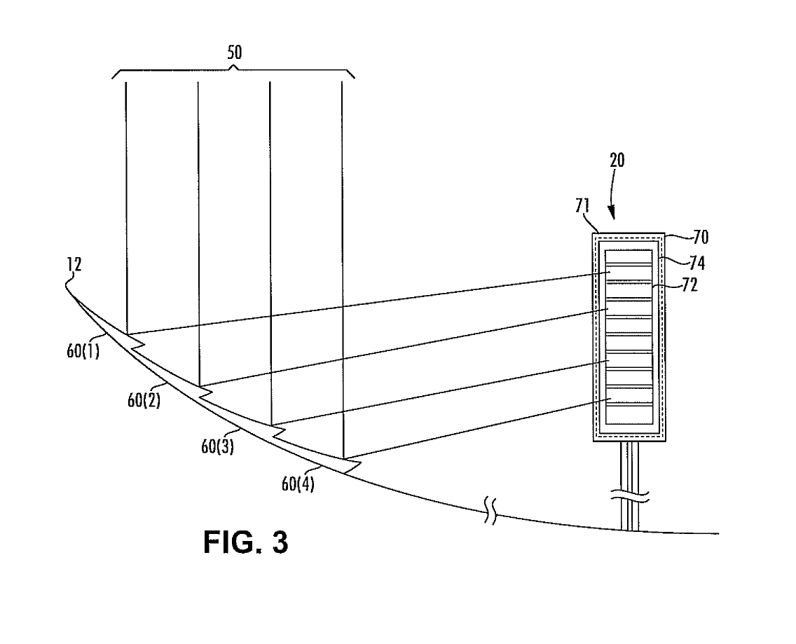

Referring now to FIGS. 2 and 3, the sidewall of the solar dish collector 12 is constructed so that there is no single or concentrated focal point on the photovoltaic cell assembly 20. Instead, the reflected sunlight 50 is diffused or spread out over a larger area so that a diffused focal point is provided.

The sidewall of the solar dish collector 12 is divided into sections 60(1)-60(n), where each sidewall section is essentially a different reflector. As best illustrated in FIG. 3, each sidewall section 60(1)-60(n) may be characterized as its own parabolic. Collectively, the different sidewall sections 60(1)-60(n) form a series of steps, with each step being incrementally positioned adjacent one another.

The solar dish collector 12 may also be characterized as a Fresnel lens. The light intensity on the photovoltaic cell assembly 20 can be customized based on the number of sidewall sections 60(1)-60(n), as readily appreciated by those skilled in the art. The objective is to reduce the light intensity received by the photovoltaic cell assembly 20 so that it does not burn out prematurely, yet still efficiently generates electricity.

The illustrated photovoltaic cell assembly 20 is held within a collector housing 70. The collector housing 70 may be glass for example. To help further lower the light intensity of the reflected sunlight 50, the collector housing 70 contains a cooling liquid 71, such as water. In one embodiment, the photovoltaic cells 72 are positioned within a protective liner or bag 74 that is then exposed to the cooling liquid 71 held by the collector housing 70. Alternatively, the cooling liquid is contained within its own protective liner or bag so that the photovoltaic cells 72 are externally positioned thereto.

Each solar dish collector 12 may be formed out of a molding material comprising a thermoplastic material or a thermosetting material, as readily appreciated by those skilled in the art. The molding material may be based on a polymer or elastomer. The polymers may also be fiber-reinforced.

In forming each solar dish collector 12, a STF Sheetless ThermoForming™ process may be used to deliver a dynamically controlled layer of material directly to a mold as it is extruded. This process is a fast and cost-effective way to mold large thermoformed products with a one-step operation directly from an extruder.

Each sidewall section 60(1)-60(n) has a reflective surface that may be a reflective film or coating, for example. The coating may be a reflective paint, for example. The use of mirrors is avoided, which would significantly add to the weight of the solar dish collector 12.

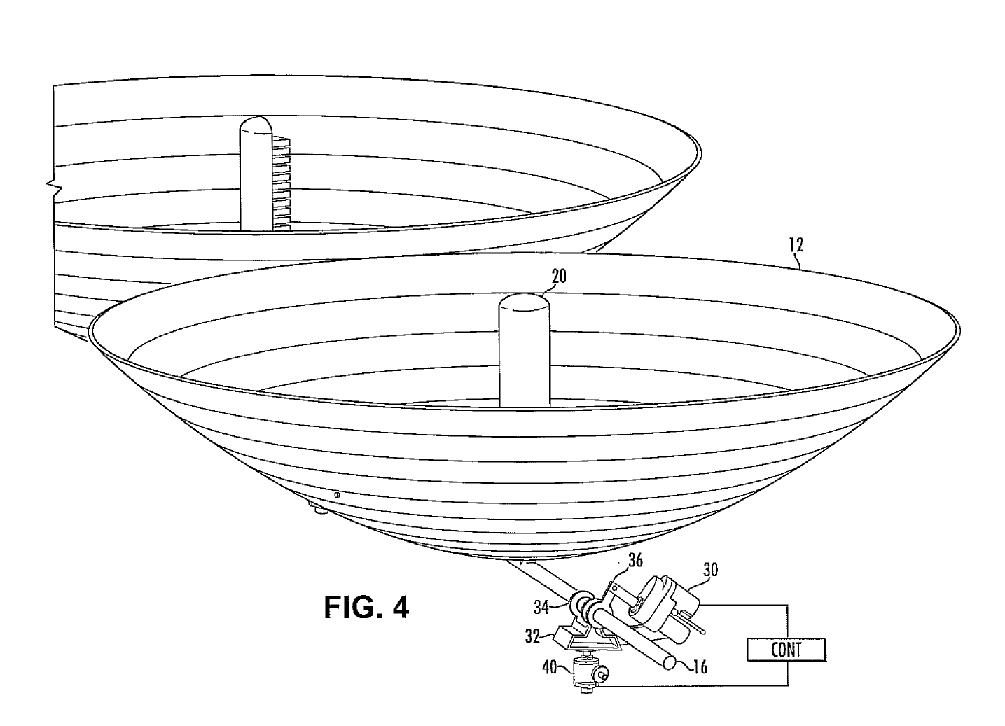

Rotation of the spaced apart solar dish collectors 12 will now be discussed in greater detail with reference to FIG. 4. The illustrated support 16 is designed to support more than one solar dish collector 12. The support 16 in turn is supported by spaced apart support devices 32. Each support device 32 includes a closed loop ring 34 through with the pipe 16 is inserted. The closed loop rings 34 are sized so that they are loosely coupled to the pipe 16. Even though open loop supports (e.g., cradles) may be used in place of the closed loop rings 34, the closed loop rings provide greater stability.

A rotator assembly 30 is coupled to the support 16 via a closed loop arm 36 through which the support 16 is inserted. In contrast, the closed loop arm 36 is tightly coupled to the support 16. Consequently, when the rotator assembly 30 moves the closed loop arm 36, the solar dish collectors 12 coupled to the pipe 16 also rotates.

Rotation of the support 16 causes the solar dish collectors 12 to rotate in a 2-axis direction, which is an east-west direction to track movement of the sun throughout the day. An advantage of this configuration is that one rotator assembly 30 is used to rotate more than one solar dish collector 12. This provides a cost effective approach for rotating several solar dish collectors 12 at one time as compared to each solar dish collector having its own rotator assembly.

To tilt the solar dish collectors 12 to compensate for the seasonal rotation of the sun, a tilt assembly 40 is provided. As illustrated in FIG. 4, a tilt assembly 40 is positioned under the support device 32 adjacent the rotator assembly 30. An advantage of this configuration is that one tilt assembly 40 is used to tilt more than one solar dish collector 12. Also, rotation/tilt of the solar dish collectors 12 is about one axis instead of two axes. Depending on the length of the support 16 and how many solar dish collectors 12 are coupled thereto, more than one tilt assembly may be used, as readily appreciated by those skilled in the art.

The support 16 is lifted so that the solar dish collectors 12 are moved in a north-south direction to increase the surface area of the collectors as the sun moves during its seasonal rotation. The tilt assembly 40 may be a jackscrew, for example. Rotation of the solar dish collectors 12 throughout the year may be within plus/minus 10 degrees, for example.

A controller 42 is connected to the rotator assembly 30 as well as to the tilt assembly 40 for control thereof so that pipe 16 is incrementally adjusted to provide the desired rotation, as readily appreciated by those skilled in the art. Operation of the controller 42 may be based on stored data or in response to a sun position sensor, for example. In lieu of the controller 42 providing control to the tilt assembly 40, a mechanical adjustment may be made by a person.

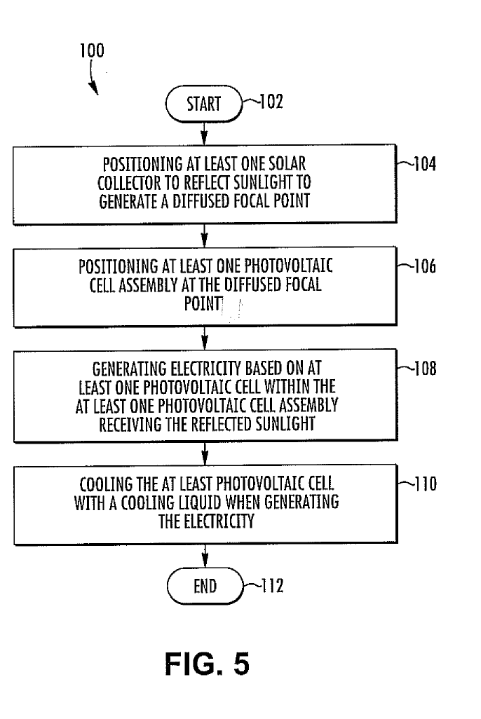

Another aspect is directed to a method for generating electricity using a solar energy collector system 10 as described above. Referring now to the flowchart 100 illustrated in FIG. 5, from the start (Block 102), the method comprises positioning the at least one solar collector 12 at Block 104 to reflect the sunlight to generate a diffused focal point, and positioning the at least one photovoltaic cell assembly 20 at the diffused focal point at Block 106. The electricity is generated at Block 108 based on the at least one photovoltaic cell 72 receiving the reflected sunlight. The method may further comprise at Block 110 cooling the at least photovoltaic cell 72 with a cooling liquid 71 when generating the electricity. The method ends at Block 112.

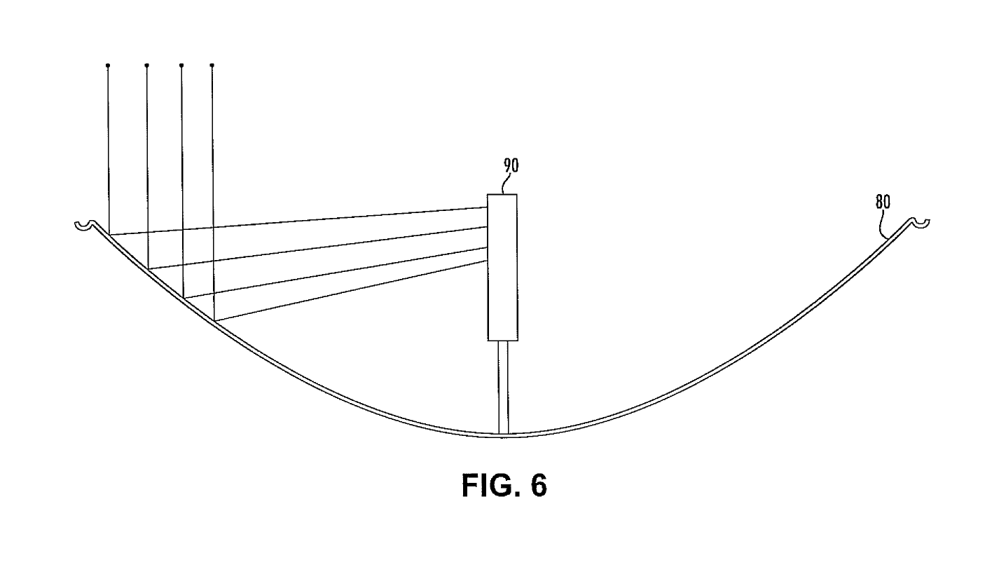

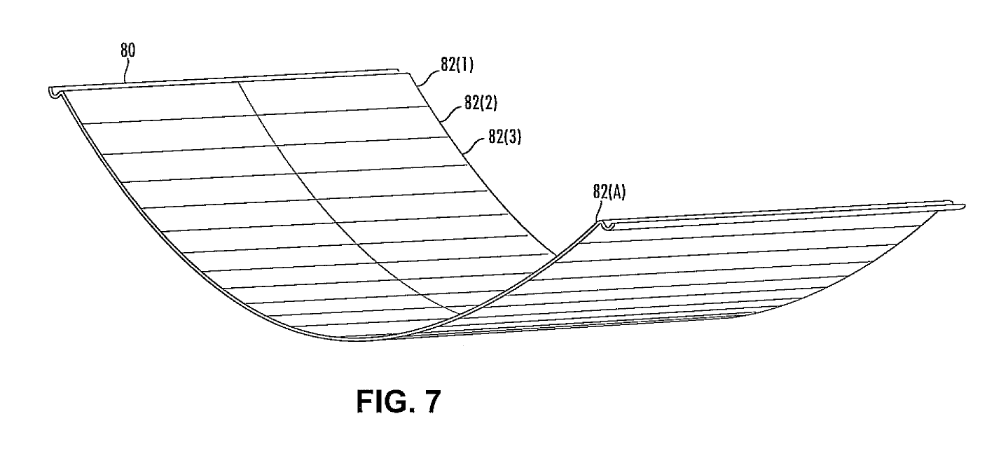

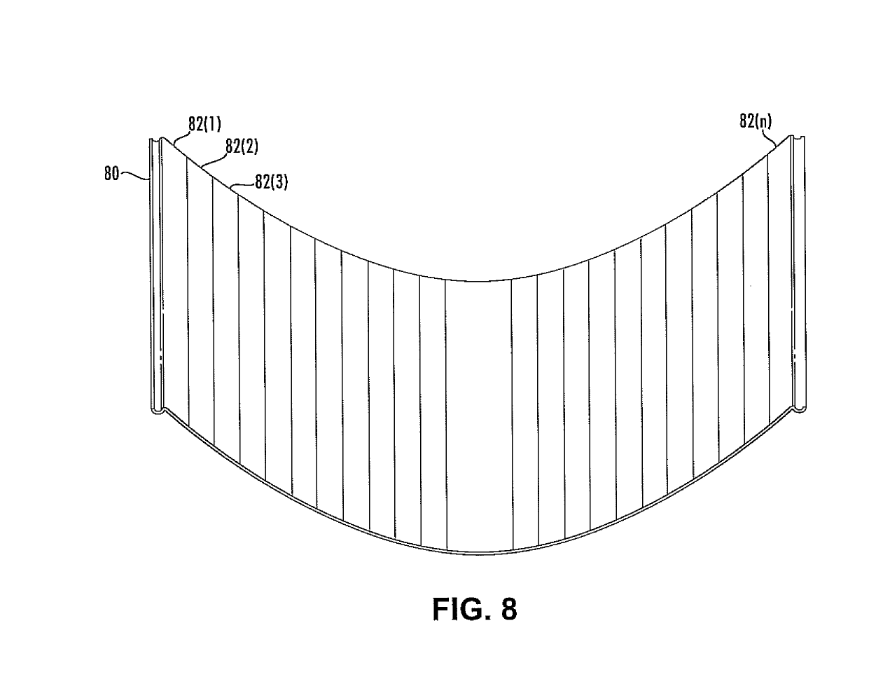

The concept of forming a solar dish collector to reflect diffused sunlight may also be applied to other types of solar collectors, such as a parabolic trough 80, for example, as illustrated in FIGS. 6-8. Similar to the sidewall of the solar dish collector 12, the sidewall of the parabolic trough 80 is divided into sections 82(1)-82(n), where each sidewall section is essentially a different reflector. Collectively, the different sidewall sections 82(1)-82(n) form a series of steps, with each step being incrementally positioned for directing diffused sunlight to a collector assembly 90.

The collector assembly 90 may also be a photovoltaic cell assembly. Alternatively, the collector assembly may be configured as a conduit circulating a heat transfer liquid (i.e., a fluid), where it will be heated by the sun's energy.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed:

1. A solar energy collector system comprising:
at least one solar collector configured to reflect sunlight to a diffused focal point; and
at least one photovoltaic cell assembly carried by said at least one solar collector and comprising
a collector housing positioned at the diffused focal point to receive the reflected sunlight, and
a plurality of photovoltaic cells within said collector housing to generate electricity based on the reflected sunlight.

2. The solar energy collector system according to claim 1 wherein said at least one photovoltaic cell assembly further comprises a cooling liquid within said collector housing to cool said plurality of photovoltaic cells when generating the electricity.

3. The solar energy collector system according to claim 2 wherein said at least one photovoltaic cell assembly further comprises a protective liner covering said at least one photovoltaic cell to prevent contact with said cooling liquid.

4. The solar energy collector system according to claim 2 wherein said at least one photovoltaic cell assembly further comprises a protective liner enclosing said cooling liquid to prevent contact with said at least one photovoltaic cell.

5. The solar energy collector system according to claim 1 wherein said at least one solar collector comprises a plurality of stepped sidewall sections adjacent one another to generate the diffused focal point.

6. The solar energy collector system according to claim 1 wherein said at least one solar collector is configured as a Fresnel lens.

7. The solar energy collector system according to claim 1 wherein said at least one solar collector is formed as a monolithic unit.

8. The solar energy collector system according to claim 7 wherein said at least one solar collector comprises at least one of a thermoplastic material and a thermosetting material.

9. The solar energy collector system according to claim 1 wherein said at least one solar collector comprises a reflective surface comprising at least one of a reflective film and a reflective coating.

10. The solar energy collector system according to claim 1 wherein said at least one solar collector is configured as a dish.

11. The solar energy collector system according to claim 1 further comprising:
a support for carrying said at least one solar collector; and
a rotator assembly configured to rotate said support and said at least one solar collector based on position of the sun.

12. The solar energy collector system according to claim 11 further comprising at least one tilt assembly configured to adjust a latitudinal angle of said support and said at least one solar collector with respect to ground.

13. A solar energy collector system comprising:
a plurality of solar collectors, each solar collector configured as a Fresnel lens to reflect sunlight to a respective diffused focal point;
a plurality of photovoltaic cell assemblies, each photovoltaic cell assembly positioned at the diffused focal point of a respective solar collector and comprising a plurality of photovoltaic cells to generate electricity based on the reflected sunlight;
a support for carrying said plurality of solar collectors; and
a rotator assembly configured to rotate said support and said plurality of solar collectors based on position of the sun.

14. The solar energy collector system according to claim 13 wherein each photovoltaic cell assembly further comprises:
a collector housing positioned at the diffused focal point and enclosing said plurality of photovoltaic cells; and
a cooling liquid within said collector housing to cool said plurality of photovoltaic cells when generating the electricity.

15. The solar energy collector system according to claim 14 wherein each photovoltaic cell assembly further comprises a protective liner covering said plurality of photovoltaic cells to prevent contact with said cooling liquid.

16. The solar energy collector system according to claim 14 wherein each photovoltaic cell assembly further comprises a protective liner enclosing said cooling liquid to prevent contact with said plurality of photovoltaic cells.

17. The solar energy collector system according to claim 13 wherein each solar collector comprises a plurality of stepped sidewall sections adjacent one another to generate the diffused focal point.

18. The solar energy collector system according to claim 13 wherein each solar collector is formed as a monolithic unit, and comprises a reflective surface comprising at least one of a reflective film and a reflective coating.

19. The solar energy collector system according to claim 13 further comprising at least one tilt assembly configured to adjust a latitudinal angle of said support and said plurality of solar collectors with respect to ground.

20. A method for generating electricity using a solar energy collector system comprising at least one solar collector, and at least one photovoltaic cell assembly carried by the at least one solar collector, the at least one photovoltaic cell assembly comprising at least one photovoltaic cell, the method comprising:
positioning the at least one solar collector to reflect the sunlight to generate a diffused focal point;
positioning the at least one photovoltaic cell assembly at the diffused focal point; and
generating the electricity based on the at least one photovoltaic cell receiving the reflected sunlight.

21. The method according to claim 20 wherein the at least one photovoltaic cell assembly further comprises a cooling liquid for cooling said at least photovoltaic cell when generating the electricity.

22. The method according to claim 21 wherein the at least one photovoltaic cell assembly further comprises a protective liner covering the at least one photovoltaic cell to prevent contact with the cooling liquid.

23. The method according to claim 21 wherein said at least one photovoltaic cell assembly further comprises a protective liner enclosing said cooling liquid to prevent contact with said at least one photovoltaic cell.

24. The method according to claim 20 wherein the at least one solar collector comprises a plurality of stepped sidewall sections adjacent one another to generate the diffused focal point.

25. The method according to claim 20 wherein the solar energy collector system further comprises a support for carrying the at least one solar collector, and a rotator assembly configured to rotate the support and the at least one solar collector based on position of the sun.

26. The method according to claim 20 wherein the solar energy collector system further comprises at least one tilt assembly for adjusting a latitudinal angle of the support and the at least one solar collector with respect to ground.
